(19) United States
(12) Patent Application Publication
(10) Pub. No.: US 2015/0275368 A1
(43) Pub. Date: Oct. 1, 2015

(54) Film Forming Apparatus Using Gas Nozzles

(71) Applicant: TOKYO ELECTRON LIMITED, Tokyo (JP)

(72) Inventors: Yutaka MOTOYAMA, Oshu-shi (JP); Kohei FUKUSHIMA, Oshu-shi (JP); Masanobu MATSUNAGA, Nirasaki City (JP); Yamato TONEGAWA, Nirasaki City (JP); Keisuke SUZUKI, Nirasaki City (JP)

(21) Appl. No.: 14/666,874

(22) Filed: Mar. 24, 2015

(30) Foreign Application Priority Data
Mar. 26, 2014 (JP) 2014064225

(51) Int. Cl. C23C 16/455; C23C 16/458; C23C 16/44

(52) U.S. Cl. CPC C23C 16/45563; C23C 16/4412; C23C 16/458

(57) ABSTRACT

A film forming apparatus includes: first and second source gas nozzles installed so as to extend in an arrangement direction of the substrates, each of the source gas nozzles including a plurality of gas ejection holes formed to eject the source gas toward central regions of the substrates at height positions corresponding to gaps between the substrates; a reaction gas supply unit configured to supply the reaction gas into the reaction vessel; first and second source gas supply lines respectively connected to the first and second source gas nozzles; first and second tanks respectively installed on the first and source gas supply lines, and configured to accumulate the source gas in a pressurized state; valves respectively installed at upstream and downstream sides of the first tank and at upstream and downstream sides of the second tank; and an exhaust port configured to evacuate the interior of the reaction vessel.

### CROSS-REFERENCE TO RELATED APPLICATION

This application claims the benefit of Japanese Patent Application No. 2014-064225, filed on Mar. 26, 2014, in the Japan Patent Office, the disclosure of which is incorporated herein in its entirety by reference.

### TECHNICAL FIELD

The present disclosure relates to a film forming apparatus which performs a film forming process with respect to a plurality of substrates held in a shelf form by a substrate holder within a vertical reaction vessel.

### BACKGROUND

As one example of a process for performing film formation with respect to a semiconductor wafer (hereinafter referred to as a “wafer”), there is available a process in which reaction product layers are laminated on a wafer by alternately performing a step of supplying a source gas to the wafer and allowing a source material to be adsorbed onto the wafer and a step of causing reaction of the source material and forming a reaction product on the wafer. When the aforementioned film forming process is performed in a vertical heat treatment apparatus which implements heat treatment by having wafers held on a wafer boat at multiple stages, there is used a gas nozzle having gas ejection holes formed at the positions corresponding to the gaps between the wafers.

Within a vertical reaction vessel, wide spaces exist at the upper side or the lower side of a wafer boat. A source gas tends to stay in these spaces. Thus, the source gas is more easily spread to the wafers existing at the upper side or the lower side of the wafer boat than to the wafers existing in the central region of the wafer boat.

Thereafter, if a pattern gets miniaturized and becomes complex and if the surface area of each of the wafers grows larger, the consumption amount of the source gas is increased. It also becomes more difficult for the source gas to reach the wafers existing in the central region of a wafer arrangement zone than to reach the wafers existing in the upper and lower end regions. At this time, if the arrangement interval (pitch) of the wafers is increased, the source gas is easily spread to the wafers. It is therefore possible to solve the problem set forth above. However, this approach is not advisable because productivity may be reduced.

As a method of increasing the supply amount of a source gas, there is known a configuration in which two first source gas supply nozzles are installed within a reaction vessel of a vertical heat treatment apparatus which performs an ALD (Atomic Layer Deposition) method. Also known is a configuration which includes a main gas supply nozzle and an auxiliary gas supply nozzle for supplementing a process gas to the downstream side or the midstream side of a processing chamber. However, even if the number of gas supply nozzles is increased, there is a limit in the flow velocity of the gas ejected from the gas supply nozzles. For that reason, if the surface area of a pattern grows larger, a region where the gas is hard to reach is generated.

There is also known a technology in which a gas accumulating part is installed in a source gas supply pipe of a vertical heat treatment apparatus for implementing an ALD method and in which a source gas is accumulated in the gas accumulating part and is discharged at one time. However, if the amount of the source gas charged to the gas accumulating part is increased in order to increase the gas supply quantity, the internal pressure of a gas nozzle becomes higher and a gas phase reaction occurs within the gas nozzle. This may be a cause of the generation of particles.

### SUMMARY

Some embodiments of the present disclosure provide a film forming apparatus which can obtain high inter-plane (inter-substrate) uniformity in film thickness when a film forming process is performed by alternately supplying a source gas and a reaction gas to substrates held in a shelf form by a substrate holder within a vertical reaction vessel.

According to one embodiment of the present disclosure, a film forming apparatus is configured to form films on a plurality of substrates by alternately supplying a source gas and a reaction gas, which reacts with the source gas to form a reaction product, into the reaction vessel in a state in which a substrate holder holding the plurality of substrates in a shelf form is disposed within a vertical reaction vessel kept at a vacuum atmosphere. The film forming apparatus includes: a first source gas nozzle and a second source gas nozzle installed so as to extend in an arrangement direction of the substrates, each of the first source gas nozzle and the second source gas nozzle including a plurality of gas ejection holes formed so as to eject the source gas toward central regions of the substrates at height positions corresponding to gaps between the substrates; a reaction gas supply unit configured to supply the reaction gas into the reaction vessel; a first source gas supply line and a second source gas supply line respectively connected to the first source gas nozzle and the second source gas nozzle; a first tank and a second tank respectively installed on the first source gas supply line and the second source gas supply line, and configured to accumulate the source gas in a pressurized state; valves respectively installed at upstream and downstream sides of the first tank and at upstream and downstream sides of the second tank; and an exhaust port configured to evacuate the interior of the reaction vessel to create a vacuum. The gas ejection holes of both of the first source gas nozzle and the second source gas nozzle are disposed at a central height region in an arrangement direction of a height region where the substrates are arranged, and the gas ejection holes of at least one of the first source gas nozzle and the second source gas nozzle are disposed in regions other than the central height region.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view showing a film forming apparatus according to a first embodiment of the present disclosure.

FIG. 2 is a horizontal sectional view showing one example of the film forming apparatus.

FIG. 3 is an explanatory view showing the relationship between wafers mounted on a wafer boat and gas ejection holes of a first source gas nozzle and a second source gas nozzle.

FIG. 4 is a schematic horizontal sectional view showing another example of the film forming apparatus.

FIG. 5 is a schematic horizontal sectional view showing a further example of the film forming apparatus.

FIG. 6 is a configuration diagram showing a gas supply system of the film forming apparatus.

FIGS. 7A and 7B are process charts for explaining the operation of the film forming apparatus.

FIGS. 8A and 8B are process charts for explaining the operation of the film forming apparatus.

FIG. 9 is a vertical sectional view showing a film forming apparatus according to a second embodiment.

FIG. 10 is a schematic vertical sectional view showing another example of the film forming apparatus according to the second embodiment.

FIG. 11 is a schematic vertical sectional view showing a film forming apparatus according to a third embodiment.

FIGS. 12A and 12B are characteristic diagrams illustrating the results of evaluation tests.

FIG. 13 is a characteristic diagram illustrating the results of evaluation tests.

FIG. 14 is a characteristic diagram illustrating the results of evaluation tests.

FIGS. 15A and 15B are characteristic diagrams illustrating the results of evaluation tests.

### DETAILED DESCRIPTION

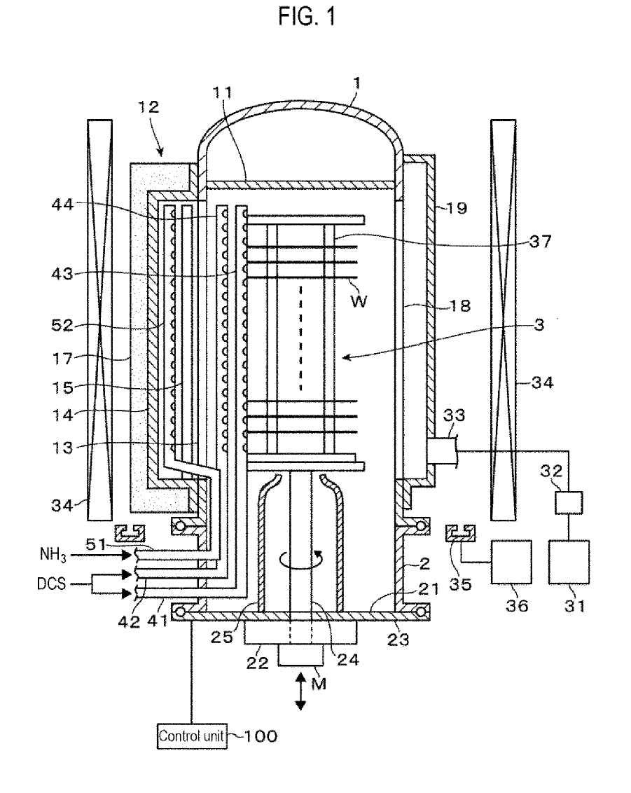

A film forming apparatus according to a first embodiment of the present disclosure will be described with reference to FIGS. 1 to 5. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In FIGS. 1 to 5, reference symbol 1 designates a vertical reaction vessel formed into a cylindrical shape by, e.g., quartz. The upper side of the reaction vessel 1 is sealed by a quartz-made top plate 11. A manifold 2 formed into a cylindrical shape by, e.g., stainless steel, is connected to the lower end side of the reaction vessel 1. The lower end portion of the manifold 2 is opened so as to form a substrate carry-in/carry-out port 21. The substrate carry-in/carry-out port 21 is air-tightly closed by a quartz-made lid 23 installed in a boat elevator 22. A rotation shaft 24 is installed to penetrate the central portion of the lid 23. A wafer boat 3 as a substrate holder is mounted on the upper end portion of the rotation shaft 24.

The wafer boat 3 includes, e.g., three support posts 37 which support outer edge portions of wafers W. The wafer boat 3 is configured to be able to hold a plurality of, e.g., 120, wafers W in a shelf form. At this time, the arrangement gap of the wafers W (the distance between the front surface of one of the wafers W and the rear surface of another wafer W positioned just above one of the wafers W) is, e.g., 8 mm. The boat elevator 22 is configured such that it can be moved up and down by a lifting mechanism not shown. The rotation shaft 24 is configured such that it can be rotated about a vertical axis by a motor M which constitutes a drive unit. In FIG. 1, reference symbol 25 designates a heat insulating unit. In this way, the wafer boat 3 is configured such that it can be moved up and down between a processing position, at which the wafer boat 3 is loaded (carried) into the reaction vessel 1 and the substrate carry-in/carry-out port 21 of the reaction vessel 1 is closed by the lid 23, and a carry-out position of the lower side of the reaction vessel 1.

A plasma generating part 12 is installed in a portion of the sidewall of the reaction vessel 1. The plasma generating part 12 is installed so as to cover a vertically elongated opening 13 formed in the sidewall of the reaction vessel 1 and is configured by air-tightly bonding a partition wall 14, which is formed into a concave cross-sectional shape and made of, e.g., quartz, to the outer wall of the reaction vessel 1. The opening 13 is vertically elongated so as to cover all the wafers W supported in the wafer boat 3. A pair of mutually-opposing plasma electrodes 15 is installed on the outer surfaces of the opposite sidewalls of the partition wall 14 so as to extend along the longitudinal direction (vertical direction) thereof. A high-frequency power supply source 16 for the generation of plasma is connected to the plasma electrodes 15 through power supply lines 161. The high-frequency power supply source 16 is configured to supply a high-frequency voltage of, e.g., 13.56 MHz, to the plasma electrodes 15 such that the plasma electrodes 15 can generate plasma. An insulating protection cover 17 made of, e.g., quartz, is installed outside the partition wall 14 so as to cover the partition wall 14.

In order to evacuate the internal atmosphere of the reaction vessel 1 and to create a vacuum, a vertically elongated exhaust port 18 is formed in a portion of the sidewall of the reaction vessel 1 in a circumferential direction, namely in a region opposing the plasma generating part 12 in this example. If the region of the wafer boat 3 in which the wafers W are arranged is defined as an arrangement region, the exhaust port 18 is formed along the arrangement direction of the wafers W so as to face the arrangement region. Thus, the exhaust port 18 is installed at the lateral side of all the wafers W.

An exhaust cover member 19 made of, e.g., quartz and formed into a substantially U-like cross-sectional shape is installed in the exhaust port 18 so as to cover the exhaust port 18. For example, the exhaust cover member 19 is configured to vertically extend along the sidewall of the reaction vessel 1. A vacuum pump 31 constituting a vacuum exhaust means and an exhaust line 33 provided with a pressure regulating valve 32 are connected to, e.g., the lower portion of the lower portion of the exhaust cover member 19. As shown in FIG. 1, a tubular heater 34 as a heating unit is installed so as to surround the periphery of the reaction vessel 1. For example, a ring-shaped air supply port 35 is installed between the reaction vessel 1 and the heater 34. A cooling gas is sent from a cooling gas supply unit 36 to the air supply port 35.

A first source gas supply line 41 and a second source gas supply line 42 for supplying a silane-based gas as a source gas, e.g., dichlorosilane (DCS: SiH₂Cl₂), are inserted through the sidewall of the manifold 2. A first source gas nozzle 43 (hereinafter referred to as a “first nozzle 43”) and a second source gas nozzle 44 (hereinafter referred to as a “second nozzle 44”) are installed in the tip portions of the first source gas supply line 41 and the second source gas supply line 42. The first nozzle 43 and the second nozzle 44 are formed of quartz pipes having, e.g., a circular cross section. As shown in FIG. 1, the first nozzle 43 and the second nozzle 44 are vertically installed at the lateral side of the wafer boat 3 within the reaction vessel 1 so as to extend along the arrangement direction of the wafers W held in the wafer boat 3. In this example, the tips of the first nozzle 43 and the second nozzle 44 are positioned, e.g., near the top portion of the wafer boat 3.

A reaction gas supply line 51 for supplying an ammonia (NH₃) gas as a reaction gas is inserted through the sidewall of the manifold 2. A reaction gas nozzle 52 formed of, e.g., a quartz pipe and constituting a reaction gas supply unit is installed in the tip portion of the reaction gas supply line 51. The reaction gas refers to a gas that reacts with molecules of a source gas and generates a reaction product. The reaction gas nozzle 52 extends upward within the reaction vessel 1. The reaction gas nozzle 52 is bent in the intermediate portion thereof and is disposed within the plasma generating part 12.

In the first nozzle 43 and the second nozzle 44, a plurality of gas ejection holes 431 and 441 for ejecting a source gas are formed along the longitudinal direction thereof at a specified interval. As schematically shown in FIG. 3, the gas ejection holes 431 and 441 are disposed at the height positions corresponding to the gaps between the wafers W held by the wafer boat 3 and are formed so as to eject a source gas toward the central portions of the wafers W. Furthermore, the gas ejection holes 431 and 441 of the first nozzle 43 and the second nozzle 44 are disposed over an entire height region of the wafer boat 3 in which the wafers W are arranged.

The height positions of the gas ejection holes 431 and 441 may be set such that a source gas is supplied from the gas ejection holes 431 and 441 to the regions of ±1 mm of the height positions of the centers P of the gaps between the wafers W. The height positions of the gas ejection holes 431 and 441 are set in alignment with the height positions of the centers P. Moreover, the gas ejection holes 431 and 441 are formed at a diameter of, e.g., 1.5 (p, and at an arrangement interval (pitch) of, e.g., 8 mm. The size, number, position and arrangement interval of the gas ejection holes 431 are set to correspond to those of the gas ejection holes 441.

As will be described later, a source gas is ejected from the gas ejection holes 431 and 441 at a high flow velocity. In order to suppress interference of gas streams, the height positions of the gas ejection holes 431 may be aligned with those of the gas ejection holes 441. By the expression that “the height positions are aligned”, it is meant that the height positions of the vertical centers of the gas ejection holes 431 are aligned with those of the gas ejection holes 441. Interference of gas streams can be suppressed as long as the height positions of the vertical centers of the gas ejection holes 431 and 441 corresponding to each other are deviated within a range of 1 mm. This deviation is also included in the range of alignment of the height positions. In the reaction gas nozzle 52, a plurality of gas ejection holes 521 for ejecting a reaction gas toward the wafers W are formed along the longitudinal direction thereof at a specified interval.

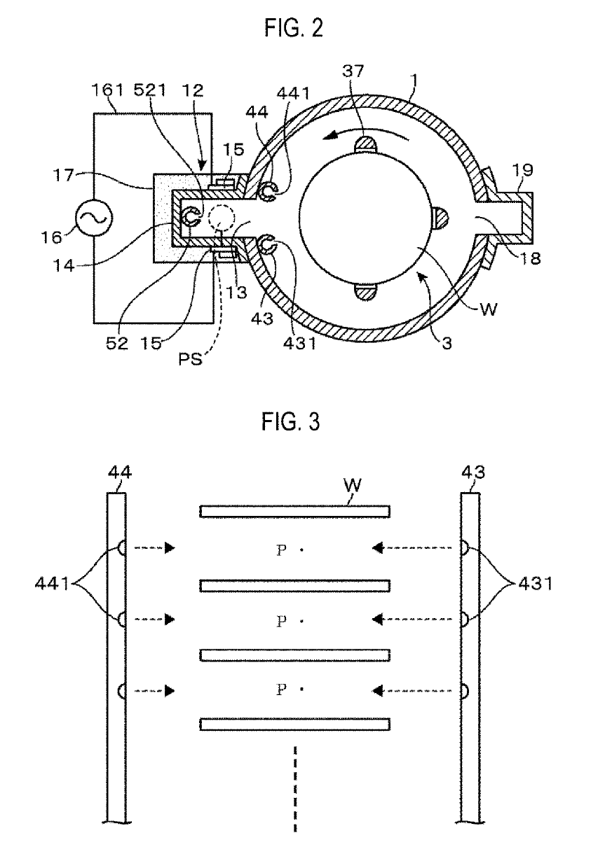

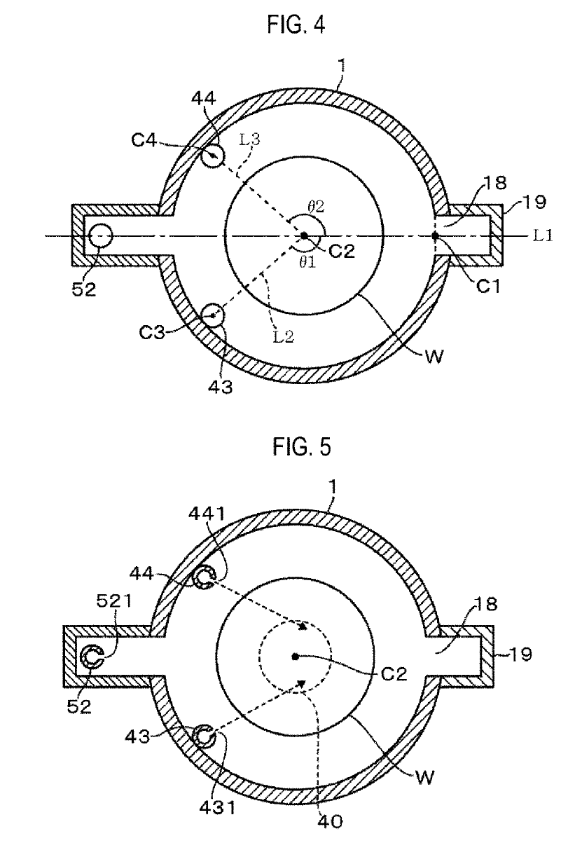

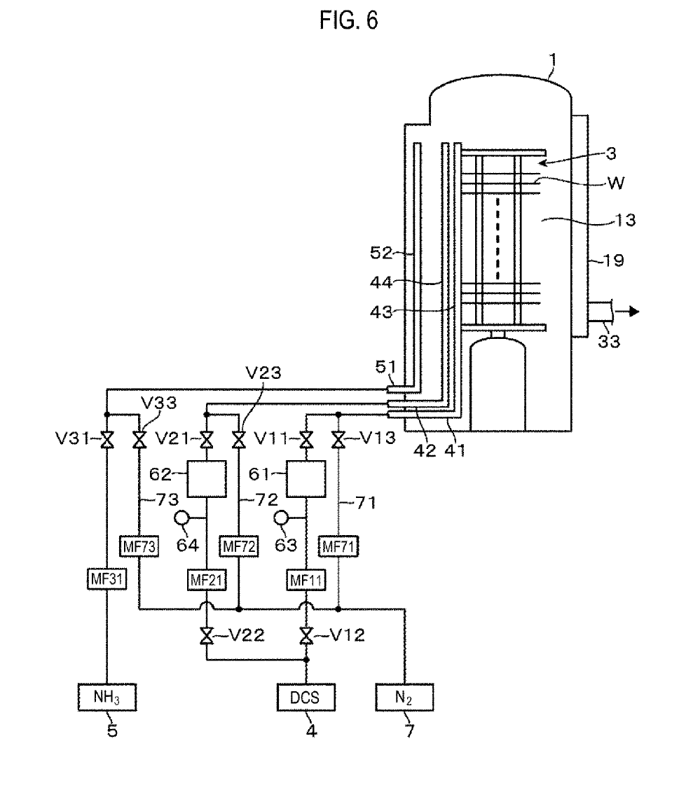

As shown in FIGS. 2, 4 and 5, the first nozzle 43 and the second nozzle 44 are disposed such that the opening 13 of the plasma generating part 12 are therebetween. In FIGS. 1 and 6, for the sake of convenience, the first nozzle 43 and the second nozzle 44 are depicted as if they are disposed side by side when seen in a side view. A description will be made in more detail with reference to FIG. 4. FIG. 4 is a schematic horizontal sectional view of the reaction vessel 1. FIG. 4 shows that the wafers W mounted on the wafer boat 3 (not shown), the first nozzle 43, the second nozzle 44 and the reaction gas nozzle 52 are disposed within the reaction vessel 1. A straight line L1 in FIG. 4 is a first straight line which, when seen in a plane view, interconnects the left-right-direction center C1 of the exhaust port 18 and the center C2 of the wafers W mounted to the wafer boat 3. The left-right-direction center C1 of the exhaust port 18 refers to the circumferential-direction center of the portion of the sidewall of the reaction vessel 1 cut out as the exhaust port 18 (the portion indicated by a dot line in FIG. 4) when seen in a plane view. The reaction gas nozzle 52 of this example is installed such that at least a portion thereof is positioned on the first straight line L1.

In this example, the first nozzle 43 and the second nozzle 44 are installed at the positions symmetrical in the left-right direction with respect to the first straight line L1. When the reaction vessel 1 is seen in a plane view, an opening angle θ1 between the first nozzle 43 and the left-right-direction center C1 of the exhaust port 18 about the center of the substrates and an opening angle θ2 between the second nozzle 44 and the left-right-direction center C1 of the exhaust port 18 about the center of the substrates are 90 degrees or more and less than 180 degrees. That is to say, as shown in FIG. 4, it may be preferable in some embodiments that, when seen in a plane view, the angle θ1 between the second straight line L2 interconnecting the center C3 of the first nozzle 43 and the center C2 of the wafers W and the first straight line L1 is set 90 degrees or more and less than 180 degrees, e.g., 135 degrees or more and 175 degrees or less. Similarly, it may be preferable in other embodiments that, when seen in a plane view, the angle θ2 between the third straight line L3 interconnecting the center C4 of the second nozzle 44 and the center C2 of the wafers W and the first straight line L1 is set 90 degrees or more and less than 180 degrees, e.g., 135 degrees or more and 175 degrees or less. In this example, the angles θ1 and θ2 are respectively set 165 degrees. As mentioned above, the first nozzle 43 and the second nozzle 44 are installed at the positions symmetrical in the left-right direction with respect to the first straight line L1. Thus, the angle θ1 and the angle θ2 become equal to each other.

As described above, the gas ejection holes 431 of the first nozzle 43 and the gas ejection holes 441 of the second nozzle 44 are configured to eject a source gas toward the central portions of the wafers W. By the expression that the source gas is ejected toward the central portions of the wafers W, it is meant that the gas ejection holes 431 and 441 are oriented toward the central portions of the wafers W. This definition is intended to encompass not only a case where the gas ejection holes 431 and 441 are oriented toward the centers C2 of the wafers W but also a case where, as shown in FIG. 5, the gas ejection holes 431 and 441 are oriented toward the inside of a region of a circle 40 having a center coinciding with the center C2 of the wafer and having a radius equal to or smaller than one half of the radius of the wafers W.

Subsequently, the gas supply system will be described with reference to FIG. 6. The first source gas supply line 41 is connected at its one end to a supply source 4 of dichlorosilane as a source gas and is provided with a valve V11, a first tank 61, a pressure detecting unit 63, a flow rate adjusting unit MF11 and a valve V12 which are disposed in the named order from the side of the reaction vessel 1. The first source gas supply line 41 is branched at the downstream side of the valve V11 and is connected to a supply source 7 of a nitrogen gas as a substituting gas through a first substituting gas supply line 71 provided with a valve V13 and a flow rate adjusting unit MF71. The valves are used to supply and cut off a gas. The flow rate adjusting units are used to adjust a gas supply amount. This holds true for the valves and the flow rate adjusting units to be described later.

Similarly, the second source gas supply line 42 is connected at its one end to the supply source 4 of dichlorosilane as a source gas and is provided with a valve V21, a second tank 62, a pressure detecting unit 64, a flow rate adjusting unit MF21 and a valve V22 which are disposed in the named order from the side of the reaction vessel 1. The second source gas supply line 42 is branched at the downstream side of the valve V21 and is connected to the supply source 7 of a nitrogen gas through a second substituting gas supply line 72 provided with a valve V23 and a flow rate adjusting unit MF72.

If a gas is introduced into the first tank 61 and the second tank 62 by closing the valves V11 and V21 disposed at the downstream side thereof and opening the valves V12 and V22 disposed at the upstream side thereof, the gas is accumulated within the first tank 61 and the second tank 62. The internal pressures of the first and second tanks 61 and 62 are increased by continuously introducing the gas into the first and second tanks 61 and 62. The first and second tanks 61 and 62 are made of, e.g., stainless steel. The first and second tanks 61 and 62 have a pressure resistance of, e.g., 93.3 kPa and an internal volume of, e.g., about 1 liter.

The reaction gas supply line 51 is connected at its one end to a supply source 5 of an ammonia gas as a reaction gas and is provided with a valve V31 and a flow rate adjusting unit MF31 which are disposed in the named order from the side of the reaction vessel 1. The reaction gas supply line 51 is branched at the downstream side of the valve V31 and is connected to the supply source 7 of a nitrogen gas through a substituting gas supply line 73 provided with a valve V33 and a flow rate adjusting unit MF73.

The film forming apparatus having the configuration described above is connected to a control unit 100 as shown in FIG. 1. The control unit 100 is formed of a computer including a CPU and a memory unit, both of which are not shown. The memory unit stores a program which incorporates a step (command) group on the operation of the film forming apparatus, namely the control executed when performing a film forming process with respect to the wafers W within the reaction vessel 1. The program is stored in a storage medium such as, a hard disk, a compact disk, a magneto-optical disk or a memory card, and is installed from the storage medium into the computer.

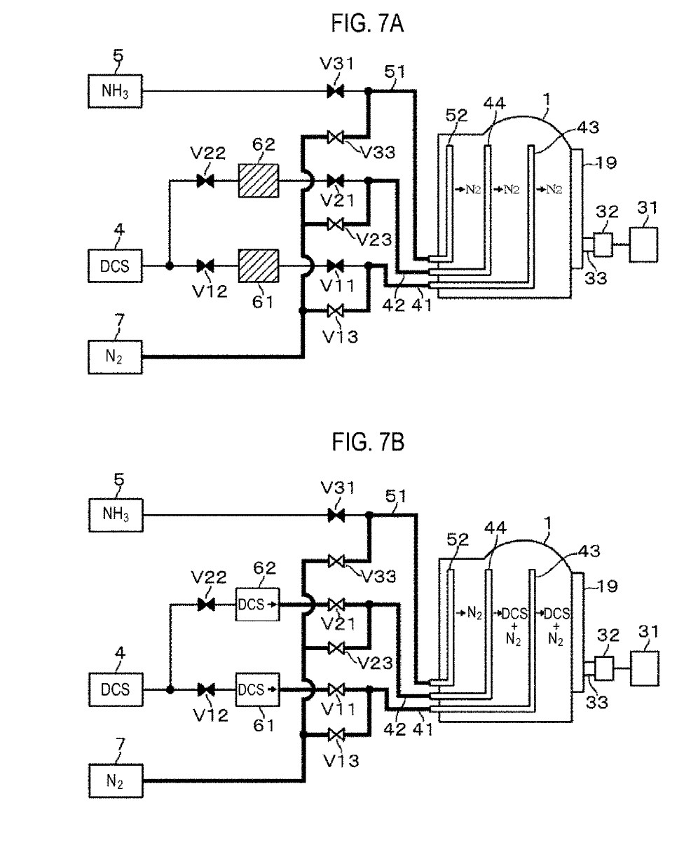

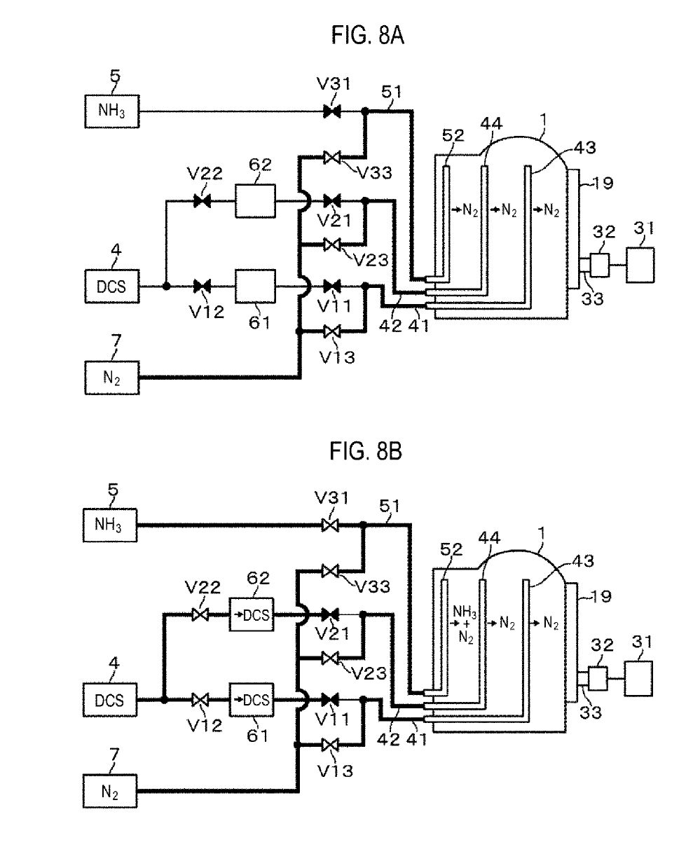

Next, the operation of the present film forming apparatus will be described with reference to FIGS. 7 and 8. FIG. 7A illustrates a state in which the wafer boat 3 holding unprocessed wafers W is carried (loaded) into the reaction vessel 1 and the interior of the reaction vessel 1 is set at a vacuum atmosphere of about 13.33 Pa (0.1 Torr⁻) by the vacuum pump 31. The wafers W are heated to a predetermined temperature, e.g., 500 degrees C., by the heater 34. The wafer boat 3 is under rotation. The first tank 61 and the second tank 62 are filled with a dichlorosilane gas in advance until the internal pressure thereof becomes, e.g., 33.33 kPa (250 Torr⁻) or more and 53.33 kPa (400 Torr⁻) or less. The internal pressures of the first tank 61 and the second tank 62 during pressurization are set to be equal to each other. Furthermore, the internal pressures of the first tank 61 and the second tank 62 during pressurization are set at a pressure which can suppress generation of a gas phase reaction within the first and second source gas supply lines 41 and 42 and the first and second nozzles 43 and 44 when a source gas is supplied respectively from the first and second tanks 61 and 62 into the reaction vessel 1 as will be described later.

In this state, the valves V13, V23 and V33 are opened. A nitrogen gas is supplied into the reaction vessel 1 through the first nozzle 43, the second nozzle 44 and the reaction gas nozzle 52 at a flow rate of, e.g., 3,000 sccm for, e.g., 3 seconds (Step S1). At this time, the pressure regulating valve 32 is kept fully opened. In FIGS. 7 and 8, the valves kept opened are indicated in white and the valves kept closed are indicated in black.

Subsequently, as shown in FIG. 7B, the valves V11 and V21 are opened and the dichlorosilane gas existing within the first tank 61 and the second tank 62 are ejected from the first nozzle 43 and the second nozzle 44 for, e.g., 3 seconds. At the same time, the nitrogen gas is ejected from the first nozzle 43, the second nozzle 44 and the reaction gas nozzle 52 at a flow rate of, e.g., 3,000 sccm (Step S2).

The interior of the reaction vessel 1 is set at a vacuum atmosphere. Therefore, if the valves V11 and V21 are opened, the dichlorosilane gas is abruptly discharged from the first and second tanks 61 and 62 and is ejected into the reaction vessel 1 after flowing through the first and second nozzles 43 and 44 at a predetermined flow velocity. At this time, the flow velocity of the dichlorosilane gas ejected from the first nozzle 43 and the second nozzle 44 is 250 cc/min or more and 350 cc/min or less, e.g., 300 cc/min. Within the reaction vessel 1, the dichlorosilane gas flows toward the exhaust port 18. Then the dichlorosilane gas is discharged to the outside through the exhaust line 33. In this example, the first nozzle 43 and the second nozzle 44 are installed so as to oppose the exhaust port 18 across the wafers W. Thus, the dichlorosilane gas flows along the surfaces of the wafers W from one side to the other side, whereby the molecules of the dichlorosilane gas are adsorbed onto the surfaces of the wafers W.

The dichlorosilane gas existing within the first and second tanks 61 and 62 is discharged for, e.g., 3 seconds. Thereafter, a nitrogen gas as a substituting gas is supplied into the reaction vessel 1, thereby purging the interior of the reaction vessel 1 with the nitrogen gas. In this process, as shown in FIG. 8A, the valves V11 and V21 are closed and the valves V13, V23 and V33 are opened. The nitrogen gas is supplied from the first nozzle 43 and the second nozzle 44 at a flow rate of, e.g., 1,000 sccm and from the reaction gas nozzle 52 at a flow rate of, e.g., 5,000 sccm for, e.g., 6 seconds (Step S3). Subsequently, the flow rate of the nitrogen gas supplied from the first nozzle 43, the second nozzle 44 and the reaction gas nozzle 52 is changed to, e.g., 200 sccm, in which state the nitrogen gas is supplied for, e.g., 3 seconds (Step S4). In this way, the dichlorosilane gas existing within the reaction vessel 1 is substituted by the nitrogen gas.

Subsequently, an ammonia gas as a reaction gas is supplied into the reaction vessel 1. In this process, as shown in FIG. 8B, electric power of, e.g., 100 W, is supplied to the high-frequency power supply source 16. The valve V31 is opened. The ammonia gas is supplied into the reaction vessel 1 through the reaction gas nozzle 52 at a flow rate of, e.g., 6,000 sccm for, e.g., 9 seconds (Step S5). Furthermore, the nitrogen gas is supplied from the first nozzle 43, the second nozzle 44 and the reaction gas nozzle 52 at a flow rate of, e.g., 200 sccm.

Thus, within the plasma generating part 12, plasma is generated in the region PS indicated by a dot line in FIG. 2. Active species such as, N radicals, NH radicals, NH₂ radicals and NH₃ radicals, are generated and are adsorbed onto the surfaces of the wafers W. On the surfaces of the wafers W, the molecules of the dichlorosilane gas react with the active species of NH₃, thereby forming thin silicon nitride films (SiN films). After the ammonia gas is supplied in this way, the valve V31 is closed to stop the supply of the ammonia gas. The high-frequency power supply source 16 is kept turned on, thereby allowing a reaction to occur for, e.g., 11 seconds (Step S6). At Step S6, the nitrogen gas is supplied from the first nozzle 43, the second nozzle 44 and the reaction gas nozzle 52 into the reaction vessel 1 at a flow rate of, e.g., 200 sccm.

In the meantime, the dichlorosilane gas is charged to the first and second tanks 61 and 62 while supplying the ammonia gas into the reaction vessel 1 at Step S5. That is to say, as shown in FIG. 8B, the valves V11 and V21 are closed and the valves V12 and V22 are opened. The dichlorosilane gas is supplied into the first and second tanks 61 and 62 at a flow rate of, 2,000 sccm for, e.g., 9 seconds. Thereafter, the valves V12 and V22 are closed. Thus, the internal pressure of the first and second tanks 61 and 62 is gradually increased to, e.g., 33.33 kPa (250 Torr) or more and 53.33 kPa (400 Torr) or less.

After Step S6 is completed, the high-frequency power supply source 16 is turned off and Step S1 described above is performed again. That is to say, the nitrogen gas is supplied from the first nozzle 43, the second nozzle 44 and the reaction gas nozzle 52 into the reaction vessel 1 at a flow rate of, e.g., 3,000 sccm for, e.g., 3 seconds, whereby the ammonia gas existing within the reaction vessel 1 is substituted by the nitrogen gas. By repeating the series of steps mentioned above, a thin SiN film is laminated layer by layer on the surface of the wafer W. As a result, a SiN film having a desired thickness is formed on the surface of the wafer W.

After the film forming process is performed in this way, for example, the valves V13, V23 and V33 are opened and the remaining valves are closed. The nitrogen gas is supplied into the reaction vessel 1. The internal pressure of the reaction vessel 1 is restored to the atmospheric pressure. Subsequently, the wafer boat 3 is carried out (unloaded). The processed wafers W are removed from the wafer boat 3 and the unprocessed wafers W are mounted to the wafer boat 3.

In the aforementioned example, when charging the dichlorosilane gas to the first and second tanks 61 and 62, the supply amount and the supply time of the dichlorosilane gas are set such that the internal pressures of the first and second tanks 61 and 62 become a predetermined pressure at a predetermined time. The opening and closing of the valves V11, V12, V21 and V22 are controlled based on the supply time. In this example, the internal pressures of the first and second tanks 61 and 62 during pressurization are set to be equal to each other. This means that the supply amount of the dichlorosilane gas and the opening/closing timings of the valves at the first tank 61 are equal to the supply amount of the dichlorosilane gas and the opening/closing timings of the valve at the second tank 62. However, depending on the thickness of the films thus formed and the fineness of the patterns (the surface area of the wafers), the internal pressures of the first and second tanks 61 and 62 during pressurization may be set so as to differ from each other and the flow velocities of the source gas ejected from the first nozzle 43 and the second nozzle 44 may be controlled so as to differ from each other.

According to the embodiment described above, when the film forming process is performed by alternately supplying the source gas and the reaction gas into the vertical reaction vessel kept at a vacuum atmosphere, the source gas accumulated within the first tank 61 and the second tank 62 at an increased pressure is supplied through the first nozzle 43 and the second nozzle 44. The gas ejection holes of the first and second gas nozzles are disposed in an entire arrangement-direction region of the height region in which the wafers W are arranged. Since the first and second tanks 61 and 62 for increasing the pressure are independently installed in the first and second nozzles 43 and 44, it is possible to supply the source gas into the reaction vessel 1 at a large flow rate. Thus, the source gas is sufficiently spread over the wafers W held in the wafer boat 3. It is therefore possible to obtain high inter-plane uniformity in film thickness.

As described above, the first and second tanks 61 and 62 for increasing the pressure are independently installed in the first and second nozzles 43 and 44. Therefore, even if the internal pressures of the respective first and second tanks 61 and 62 are not made so high, it is possible to supply the source gas into the reaction vessel 1 at a large flow rate. That is to say, even if the source gas is supplied into the reaction vessel 1 by increasing the internal pressures of the first and second tanks 61 and 62 to such a pressure that a gas phase reaction is not generated in the gas flow path existing at the downstream side of the first and second tanks 61 and 62, it is possible to supply the source gas into the reaction vessel 1 at such an amount that the source gas is sufficiently spread over all the wafers W. Accordingly, it is possible to instantly supply the source gas into the reaction vessel 1 at a large flow rate while suppressing generation of particles. Consequently, the source gas is evenly spread over the wafers W held in the wafer boat 3 and is adsorbed onto entire surfaces of the wafers W. Thus, a sufficient amount of source gas can be rapidly supplied to a fine pattern which has a large surface area and which consumes a large amount of source gas. As a result, the inter-plane uniformity in film thickness is improved. This makes it possible to secure high throughput. As mentioned in the evaluation tests to be described later, if the arrangement interval (pitch) of the wafers W held in the wafer boat 3 is increased, the source gas is spread over the wafers W. Thus, the inter-plane uniformity in film thickness is improved. However, the number of the wafers W mounted to the wafer boat 3 is reduced, thereby reducing the productivity. According to the method of the present embodiment, it is possible to increase the inter-plane uniformity in film thickness without reducing the productivity.

As described above, the source gas is first accumulated in the first and second tanks 61 and 62 and is instantly discharged after pressurizing the same. Thus, the flow velocities of the source gas ejected from the first and second nozzles 43 and 44 are increased to, e.g., 300 cc/min. For that reason, even if the arrangement interval of the wafers W is small, the source gas can rapidly reach the central portions of the wafers W, whereby a film is sufficiently formed not only in the peripheral edge portions of the wafers W but also in the central portions thereof. As a result, the distribution of the film thickness within the wafer plane shows a shape in which the film thickness within the wafer plane is substantially uniform or a mountain shape in which the film thickness in the central portion is larger than the film thickness in the peripheral edge region. If the distribution of the film thickness within the wafer plane shows the mountain shape, the in-plane thickness uniformity may appear to have been reduced. However, this does not matter because the film thickness can be adjusted in the etching process to be performed later. In the configuration of related art, the source gas has difficulty reaching the central portions of the wafers. Thus, the in-plane thickness distribution tends to show a valley shape in which the film thickness in the central portion is smaller than the film thickness in the peripheral edge region. The valley shape is not desirable because it may reduce the processing accuracy in the etching process.

It is now assumed that the first nozzle 43 and the second nozzle 44 are connected to a common source gas supply line and further that a common tank for increasing the pressure is used. In this case, if one wishes to eject the source gas at a large flow rate from the first nozzle 43 and the second nozzle 44, it is necessary to significantly increase the internal pressure of the tank. For that reason, if the source gas is discharged from the tank toward the first nozzle 43 and the second nozzle 44, the internal pressure of the source gas supply path existing at the downstream side of the tank becomes too high. Thus, there is a possibility that a gas phase reaction is generated and particles are generated. It is thinkable to reduce the arrangement interval of the gas ejection holes of the source gas nozzles and to increase the supply amount of the source gas. In this case, the processing accuracy becomes worse. As a result, there is a possibility that the inter-plane thickness uniformity is reduced. In order to increase the amount of the source gas ejected toward the height region which exists at the center of the arrangement direction of the wafers W and in which the source gas has difficulty in spreading, it is thinkable to increase the diameter of the gas ejection holes in the central regions of the gas nozzles. In this case, the supply amount of the source gas is changed in the boundary regions where the diameter of the gas ejection holes shows a change. It is therefore difficult to improve the inter-plane thickness uniformity.

In the embodiment described above, the source gas is ejected at a large flow rate from the first nozzle 43 and the second nozzle 44. Thus, such arrangement of the first nozzle 43 and the second nozzle 44 is devised. First, the gas ejection holes 431 and 441 are configured to eject the source gas toward the gaps between the wafers W arranged up and down. The exhaust port 18 is formed along the arrangement direction of the wafers W so as to face the arrangement region of the wafers W. For that reason, gas streams flowing toward the exhaust port 18 through the gaps between the wafers W are formed within the reaction vessel 1. Thus, the source gas is easily spread over the wafer surfaces.

When the reaction vessel 1 is seen in a plane view, an opening angle θ1 between the first nozzle 43 and the left-right-direction center C1 of the exhaust port 18 about the center of the substrates and an opening angle θ2 between the second nozzle 44 and the left-right-direction center C1 of the exhaust port 18 about the center of the substrates are 90 degrees or more and less than 180 degrees. For that reason, the first nozzle 43 and the second nozzle 44 are installed in the regions significantly spaced apart from the exhaust port 18, whereby the flow routes extending from the gas ejection holes 431 and 441 to the exhaust port 18 become longer. Therefore, even if the source gas is ejected at a large flow velocity from the gas ejection holes 431 and 441, the time of contact of the source gas with the wafers W is longer than when the flow routes are short. The source gas is easily spread over the entire surfaces of the wafers W.

Furthermore, the first nozzle 43 and the second nozzle 44 eject the source gas from the positions spaced apart from the exhaust port 18. Therefore, a region where gas streams interfere with each other is hardly generated in the flow routes of the source gas ejected from the gas ejection holes 431 and 441. This makes it possible to suppress a reduction in the gas flow velocity otherwise caused by the interference of gas streams. It is also possible to restrain the gas streams from being disturbed and to restrain the gas amount from becoming non-uniform within the wafer planes. For example, if the angle θ1 and the angle θ2 are 135 degrees or more and 175 degrees or less, the gas ejection holes 431 and 441 of the first and second nozzles 43 and 44 are oriented toward the exhaust port 18. Thus, the gas is easily spread over the entire surfaces of the wafers and the interference of the gas streams ejected from the first and second nozzles 43 and 44 is suppressed. This makes it possible to expect further improvement of the in-plane uniformity in film thickness.

On the other hand, if the angle θ1 and the angle θ2 are less than 90 degrees, the first nozzle 43 and the second nozzle 44 are positioned too close to the exhaust port 18. Therefore, the gas is hardly spread over the entire surfaces of the wafers. Moreover, if the source gas is ejected at a large flow rate from the gas ejection holes 431 and 441 positioned close to the exhaust port 18, the streams of the source gas ejected from the first nozzle 43 and the second nozzle 44 collide with each other and easily interfere with each other in the vicinity of the exhaust port 18. This may possibly reduce the in-plane film thickness uniformity. If the internal pressures of the first tank 61 and the second tank 62 are uniformly increased and if the flow rates of the source gas ejected from the first nozzle 43 and the second nozzle 44 are made uniform, the source gas is ejected at a uniform pressure from the first and second nozzles 43 and 44. Thus, the disturbance of the streams of the source gas within the planes of the wafers W is suppressed and the in-plane film thickness uniformity is improved.

Furthermore, if the first nozzle 43 and the second nozzle 44 are installed at the positions symmetrical with respect to the first straight line L1, the positional relationship between the first nozzle 43 and the exhaust port 18 is equal to the positional relationship between the second nozzle 44 and the exhaust port 18. Thus, the gas streams ejected from the first and second nozzles 43 and 44 equally flow toward the exhaust port 18. This makes it possible to increase the in-plane film thickness uniformity. In the embodiment described above, the reaction gas nozzle 52 is installed on the first straight line L1 and is located opposite the exhaust port 18 across the wafers W. For that reason, the reaction gas ejected from the reaction gas nozzle flows on the wafers W from one side toward the other side. The reaction gas is evenly supplied to the surfaces of the wafers W. The reaction of the source gas with the reaction gas is reliably generated on the entire surfaces of the wafers W. It is therefore possible to increase the in-plane film thickness uniformity. As a result of the increase of the in-plane film thickness uniformity, the inter-plane film thickness uniformity is also increased. That is to say, films can be formed with high in-plane film thickness uniformity even on the wafers W of the central region of the wafer boat 3 on which the inter-plane film thickness uniformity is worsened due to the difficulty of the source gas to reach the central region and due to the difficulty to form films. As a result, the film thickness of the wafers W of the central region of the wafer boat 3 becomes equal to the film thickness of the wafers W existing in the upper and lower regions of the wafer boat 3.

In the aforementioned example, the first tank 61 and the second tank 62 are independently installed with respect to the first nozzle 43 and the second nozzle 44. It is therefore possible to freely set the internal pressures of the first and second tanks 61 and 62. Thus, the internal pressures of the first and second tanks 61 and 62 may be changed depending on the kind of film forming process used. Since the flow velocities of the source gas supplied from the first nozzle 43 and the second nozzle 44 can be appropriately set, it is possible to increase the degree of freedom of supply of the source gas.

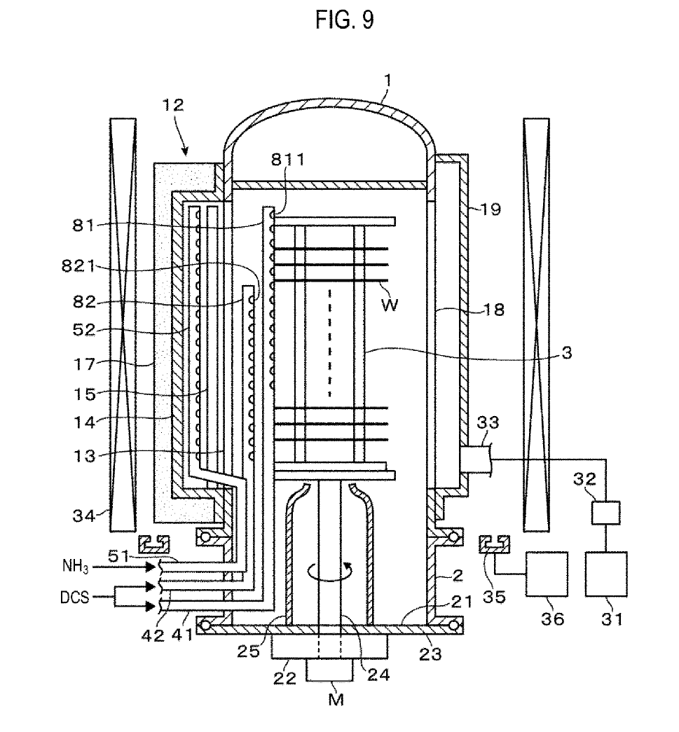

Next, a second embodiment of the present disclosure will be described with reference to FIG. 9. This embodiment is configured such that the total sum of ejection amounts of a source gas ejected from a first source gas nozzle 81 (hereinafter referred to as a “first nozzle 81”) and a second source gas nozzle 82 (hereinafter referred to as a “second nozzle 82”) becomes larger at a central height region in an arrangement direction of a height region where wafers W are arranged. Thus, the gas ejection holes 811 of the first nozzle 81 and the gas ejection holes 821 of the second nozzle 82 are formed such that the supply amount of the source gas ejected toward the central height region becomes larger than the supply amount of the source gas ejected toward the wafers W arranged in the regions other than the central height region.

With regard to the first and second nozzles 81 and 82, the points differing from the first embodiment will now be described. When the wafers W are fully mounted to the wafer boat 3, if one source gas nozzle for ejecting a source gas between the wafers W is used and if the surface areas of the wafers W are large, the film thickness distribution in the longitudinal direction of the wafer boat 3 has such a tendency that the film thickness in the central portion becomes smaller. The central height region refers to a region where the film thickness distribution in the longitudinal direction of the wafer boat 3 can be improved by making the ejection amount of the source gas ejected toward the central height region larger than the ejection amount of the source gas ejected toward the regions exiting above and below the central height region. More specifically, for example, when m wafers W are fully mounted to the wafer boat 3, the central height region refers to a region corresponding to a region spaced apart by k wafers upward and downward from an m/2th (m: even number) or (m−1)/2th (m: odd number) wafer W positioned at the midpoint in the arrangement direction. Furthermore, the central height region refers to a region which is included in a region where the number of the wafers W belonging to the region is 1/10 or more and ⅓ or less of the total number m of the wafers W. This holds true in the case of the central height region of the wafer boat 3 of the first embodiment.

In this example, as shown in FIG. 9, the gas ejection holes 811 and 821 of the first nozzle 81 and the second nozzle 82 are disposed in the central height region of the wafer boat 3. Only the gas ejection holes 811 of the first nozzle 81 are disposed in the region (upper region) existing above the central height region of the wafer boat 3. Only the gas ejection holes 821 of the second nozzle 82 are disposed in the region (lower region) existing below the central height region.

One example of the formation regions of the gas ejection holes 811 and 821 of the first nozzle 81 and the second nozzle 82 will now be described. When 120 wafers W are mounted to the wafer boat 3, the gas ejection holes 811 are formed in the first nozzle 81 so as to eject the gas toward the surfaces of the uppermost wafer W to the 80^{th} upper wafer W. The gas ejection holes 821 are formed in the second nozzle 82 so as to eject the gas toward the surfaces of the 60^{th} upper wafer W to the lowermost wafer W. The arrangement of the first and second nozzles 81 and 82, the arrangement interval and orientation of the gas ejection holes 811 and 821, the first and second source gas supply lines 41 and 42 connected to the base ends of the first and second nozzles 81 and 82, the first and second tanks 61 and 62, and other configurations are the same as those of the first embodiment described above.

The sequences of the film forming process are also the same as those of the aforementioned embodiment. The ejection timings of the source gas ejected from the first and second nozzles 81 and 82 may differ from each other. Furthermore, the ejection amounts of the source gas ejected from the first and second nozzles 81 and 82 may differ from each other. The internal pressures of the first and second tanks 61 and 62 during pressurization may differ from each other. The ejection velocities of the source gas ejected from the first and second nozzles 81 and 82 may differ from each other. The length of the second nozzle 82 is equal to the length of the first nozzle 81. It may be possible to employ a configuration in which the gas ejection holes 821 are formed in a partial region of the second nozzle 82.

According to this embodiment, the source gas is ejected from both the first nozzle 81 and the second nozzle 82 toward the wafers W arranged in the central height region of the wafer boat 3. Accordingly, the amount of the source gas supplied to the central height region in which the source gas is more difficult to spread than in the upper region or the lower region of the wafer boat 3 is larger than the amount of the source gas supplied to the upper region or the lower region. Thus, the adsorption amounts of the source gas to the wafers W become uniform in the vertical direction of the wafer boat 3, whereby the inter-plane film thickness uniformity is improved.

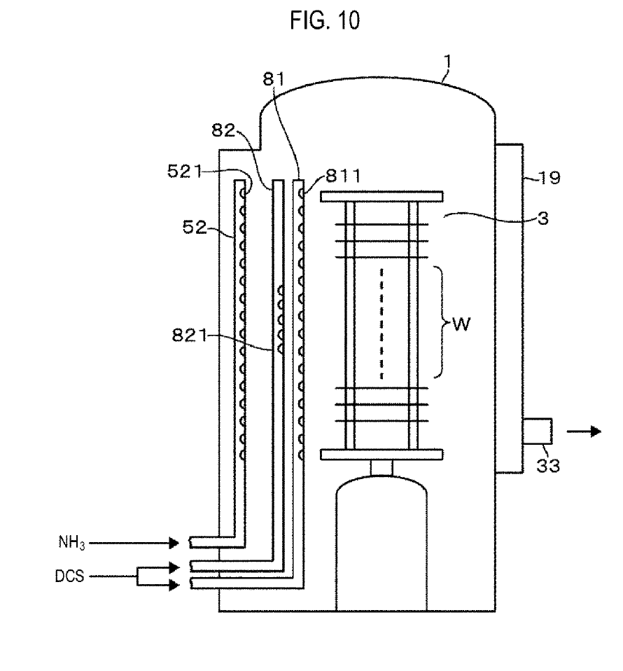

In this example, as shown in FIG. 10, the gas ejection holes 811 may be formed in the first nozzle 81 so as to eject the gas toward the entire height region where the wafers W are arranged. The gas ejection holes 821 may be formed in the second nozzle 82 so as to eject the gas toward the central height region. The shape and arrangement interval of the gas ejection holes 811 or 821 of at least one of the first nozzle 81 and the second nozzle 82 may be adjusted such that the supply amount of the source gas ejected toward the central height region of the wafer boat 3 becomes larger than the supply amount of the source gas ejected toward the regions other than the central height region. For example, the gas ejection holes 811 or 821 formed in the region of the nozzle 81 or 82 opposing the central height region may be larger in diameter or narrower in arrangement interval than the gas ejection holes 811 or 821 formed in other regions, thereby enlarging the ejection region and increasing the gas supply amount.

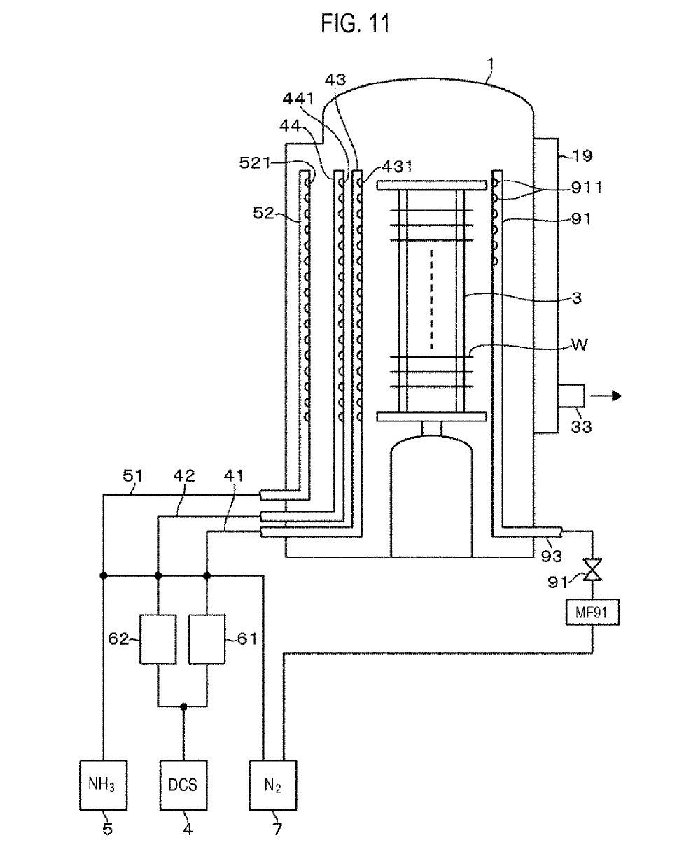

Next, a third embodiment of the present disclosure will be described with reference to FIG. 11. In this embodiment, a gas nozzle for supplying a pressure-regulating gas is installed within the reaction vessel 1 so as to extend along the arrangement direction of the wafers W. In this example, there is provided a gas nozzle 91 which supplies a pressure-regulating gas, e.g., a nitrogen gas, to the upper region of the wafer boat 3. In the gas nozzle 91, gas ejection holes 911 for supplying a nitrogen gas toward the upper region of the wafer boat 3 are formed in a mutually spaced-apart relationship. The gas nozzle 91 is connected to a supply source 7 of a nitrogen gas through a gas supply line 93 provided with a valve V91 and a flow rate adjusting unit MF91. As the pressure-regulating gas, it may be possible to use an inert gas other than the nitrogen gas.

In FIG. 11, there is shown an example in which the gas nozzle 91 is installed in the film forming apparatus of the first embodiment. Alternatively, the gas nozzle 91 may be installed in the film forming apparatus of the second embodiment. In FIG. 11, for the sake of convenience in illustration, the gas nozzle 91 is shown as if it exists at the side of the exhaust cover member 19. In reality, the gas nozzle 91 is disposed at a position where the gas nozzle 91 does not inhibit the flow of the source gas or the reaction gas ejected from the first and second nozzles 43 and 44 and the reaction gas nozzle 52. The definition on the central height region of the wafer boat 3 and other configurations remain the same as those of the embodiments described above.

As described with respect to the aforementioned embodiments, the film forming apparatus performs the film forming process within the reaction vessel 1 using one cycle which includes a source gas supply, atmosphere substitution, reaction gas supply and atmosphere substitution in the order named. Specifically, the atmosphere substitution is a process called cycle purge in which a nitrogen gas is intermittently supplied while creating a vacuum. During the series of film forming steps, the nitrogen gas is supplied from the gas nozzle 91 after completion of the cycle purge and just prior to the supply of the source gas. The nitrogen gas is supplied at a flow rate of, e.g., 3,000 sccm for, e.g., 6 seconds. After stopping the supply of the nitrogen gas, the source gas is supplied.

The exhaust line 33 is installed at the lower side of the reaction vessel 1. Therefore, if nitrogen purge is performed within a short period of time, a nitrogen gas concentration distribution having a higher concentration at a lower side than at the upper side is formed within the reaction vessel 1 at the time of completion of the nitrogen purge. In order to make the internal pressure of the reaction vessel 1 uniform in the arrangement direction of the wafers W just before the supply of the source gas, the nitrogen gas is supplied from the gas nozzle 91 to the upper region of the wafer boat 3 for a short period of time immediately before the supply of the source gas. By doing so, the source gas is supplied after the pressure distribution (the nitrogen gas concentration distribution) within the reaction vessel 1 is made uniform in the arrangement direction of the wafers W. As a result, it is possible to suppress a reduction in the inter-plane film thickness uniformity.

In the embodiments described above, the number of the source gas supply nozzles for supplying the source gas may be three or more. In this case, tanks need not be necessarily installed in the source gas supply lines for the third and subsequent nozzles other than the first nozzle 43 and the second nozzle 44. It is only necessary that the reaction gas supply unit is configured to supply the reaction gas into the space surrounded by the partition wall 14. The present disclosure is not limited to the configuration in which the reaction gas nozzle is installed to extend along the longitudinal direction of the space.

Examples of the silane-based gas includes not only the dichlorosilane gas but also a BTBAS ((bis tertiary butylamino) silane) gas, a HCD (hexadichlorosilane) gas and a 3DMAS (trisdimethylaminosilane) gas. As the substituting gas, it may be possible to use not only the nitrogen gas but also an inert gas such as an argon gas or the like.

In the film forming apparatus of the present disclosure, for example, a titanium nitride (TiN) film may be formed by using a titanium chloride (TiCl₄) gas as the source gas and using an ammonia gas as the reaction gas. As the source gas, it may be possible to use a TMA (trimethyl aluminum) gas.

Examples of the reaction for obtaining desired films by reacting the source gas adsorbed onto the surfaces of the wafers W may include an oxidation reaction using O₂, O₃, H₂O or the like, a reduction reaction using an organic acid such as H₂, HCOOH, CH₃COOH or the like or alcohol such as CH₃OH, C₂H₅OH or the like, a carbonization reaction using CH₄, C₂H₆, C₂H₂ or the like, a nitriding reaction using NH₃, NH₂NH₂, N₂ or the like, and various kinds of other reactions.

Three or four kinds of gases may be used as the source gas and the reaction gas. As one example of a case of using three kinds of gases, there is a case where a strontium titanate (SrTiO₃) film is formed using, e.g., Sr(THD)₂ (strontium bis tetramethylheptanedionate) as a Sr source material, Ti(OiPr)₂(THD)₂ (titanium bis isopropoxide bis tetramethylheptanedionate) as a Ti source material, and an ozone gas as an oxidizing gas thereof. In this case, the gases are changed over in the order of a Sr source gas, a substituting gas, an oxidizing gas, a substituting gas, a Ti source gas, a substituting gas, an oxidizing gas and a substituting gas. The first source gas nozzle and the second source gas nozzle of the present disclosure are used as a gas nozzle for at least one of the Sr source material and the Ti source material.

### EXAMPLES

### Evaluation Test 1-1

The film forming apparatus of the second embodiment shown in FIG. 9 was used. 120 wafers including product wafers W and monitoring wafers (bare wafers) were mounted to the wafer boat 3. SiN films were formed by performing a film forming process pursuant to the aforementioned sequences. Film forming conditions used at this time are as follows. The wafer temperature is 500 degrees C. The supply time of high-frequency power is 20 seconds. The total supply amount of the source gas supplied from the first nozzle 81 is 1.0 liter. The total supply amount of the source gas supplied from the second nozzle 82 is 1.0 liter. The internal pressure of the first tank 61 during pressurization is 38,000 Pa. The internal pressure of the second tank 62 during pressurization is 38,000 Pa. The monitoring wafers were respectively mounted at the uppermost stage, the center (the 60^{th} position from below) and the lowermost stage of the wafer boat 3.

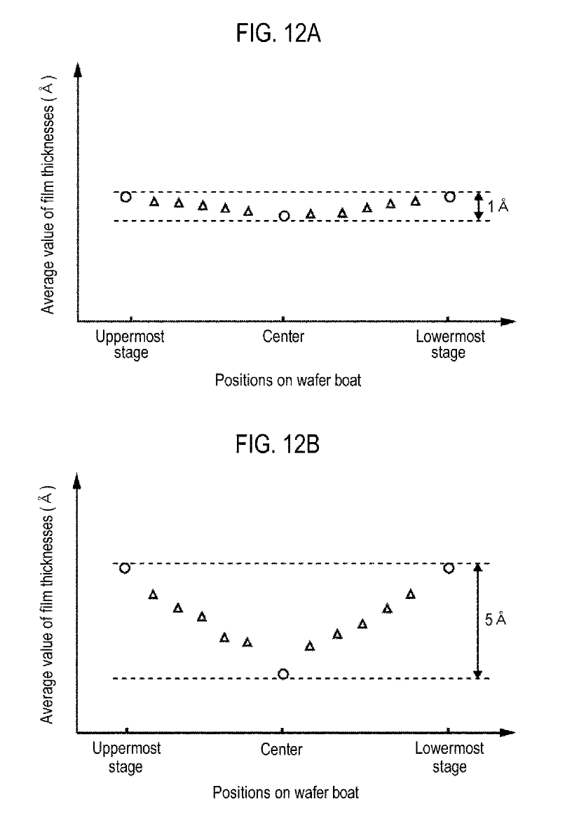

Film thicknesses were measured at 17 points within the wafer planes with respect to the product wafers arranged at 10 points in the vertical direction of the wafer boat 3 and the three monitoring wafers. The average value of the film thicknesses was calculated. The results are shown in FIG. 12A. In FIG. 12A, the horizontal axis indicates the locations on the wafer boat and the vertical axis indicates the average value of the film thicknesses. The average values of the film thicknesses for the product wafers are plotted with Δ and the average values of the film thicknesses for the monitoring wafers are plotted with ∘.

In a film forming apparatus in which only the first nozzle 43 is installed, SiN films were formed under the same film forming conditions except that the source gas is not supplied from the second nozzle 82. The average value of the film thicknesses was calculated. Just like the first embodiment, the first nozzle 43 used at this time has the gas ejection holes 431 which eject the gas toward an entire wafer arrangement region of the wafer boat 3. The results are shown in FIG. 12B.

As can be noted in FIG. 12B, in the case of using only the first nozzle 41, the film thickness of the wafer W positioned at the center of the wafer boat 3 is extremely smaller than the film thickness of the wafers W positioned at the uppermost and lowermost stages of the wafer boat 3. The difference between the film thickness of the monitoring wafers positioned at the uppermost and lowermost stages and the film thickness of the monitoring wafer positioned at the center is approximately 5 Å. From the results mentioned above, it is presumed that it is difficult to spread the source gas over the wafers W positioned in the central region of the wafer boat 3 and further that the source gas stays in the dead spaces existing at the upper side and the lower side of the wafer boat 3, and the wafers W positioned in the regions other than the central region use the source gas staying in the dead spaces to form films, as a result of which the film thickness grows larger. On the other hand, as illustrated in FIG. 12A, it was confirmed that, in the case of the configuration in which the source gas is supplied from the first nozzle 81 and the second nozzle 82 toward the central region of the wafer boat 3, the film thickness becomes substantially uniform in the vertical direction of the wafer boat 3. It was demonstrated that the inter-plane film thickness uniformity is improved in the configuration of the second embodiment of the present disclosure. The reason for the film thickness being different between the monitoring wafers and the product wafers is presumed to be that the product wafers are larger in surface area than the monitoring wafers.

### Evaluation Test 2

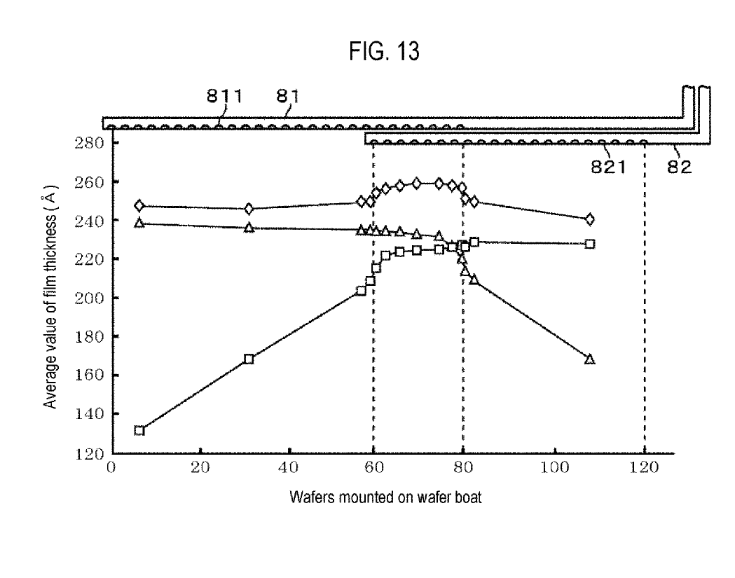

The film forming apparatus of the second embodiment shown in FIG. 9 was used. 120 product wafers W were mounted to the wafer boat 3. SiN films were formed by performing a film forming process pursuant to the aforementioned sequences. Film forming conditions used at this time are as follows. The wafer temperature is 500 degrees C. The supply time of high-frequency power is 20 seconds. The total supply amount of the source gas supplied from the first nozzle 81 is 1.14 liters. The total supply amount of the source gas supplied from the second nozzle 82 is 0.86 liters. The internal pressure of the first tank 61 is 42,000 Pa. The internal pressure of the second tank 62 during pressurization is 36,000 Pa. Film thicknesses were measured at 17 points within the wafer planes with respect to the product wafers arranged at a plurality of positions in the vertical direction of the wafer boat 3. The average value of the film thicknesses was calculated. The results are shown in FIG. 13. In FIG. 13, the horizontal axis indicates the wafers mounted on the wafer boat and the vertical axis indicates the average value of the film thicknesses which is plotted with ⋄. In the case of supplying the source gas from only the first nozzle 81 and in the case of supplying the source gas from only the second nozzle 82, SiN films were formed under the same film forming conditions. The average value of the film thicknesses was calculated in the same manner. The average values of the film thicknesses in the case of using only the first nozzle 81 are plotted with Δ and the average values of the film thicknesses in the case of using only the second nozzle 82 are plotted with □.

As a result, it was demonstrated that, in the case of supplying the source gas from both the first nozzle 81 and the second nozzle 82, the film thickness is substantially uniform and the inter-plane film thickness uniformity is improved although the film thickness in the central height region of the wafer boat 3 (in this example, the region between the position of the 60^{th} wafer from above and the position of the 80^{th} wafer from above) becomes larger than the film thickness in other regions. On the other hand, it was confirmed that, in the case of using only the first nozzle 81, the film thickness is sharply reduced at the lower side of the wafer boat 3 and further that, in the case of using only the second nozzle 82, the film thickness is sharply reduced at the upper side of the wafer boat 3.

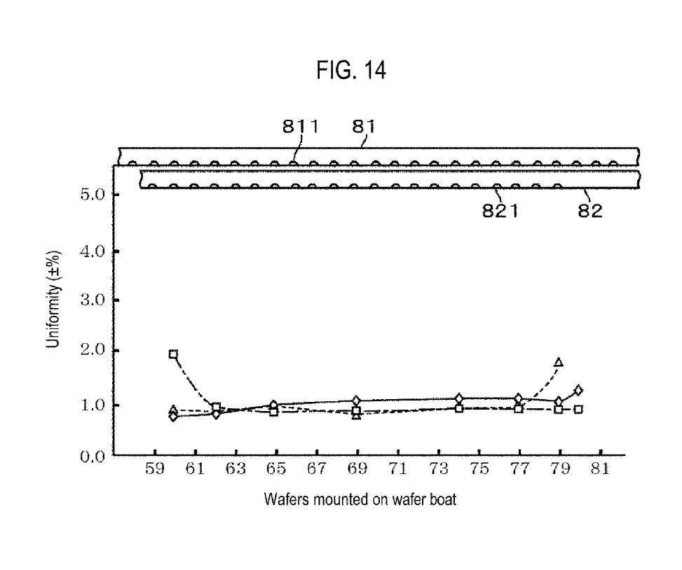

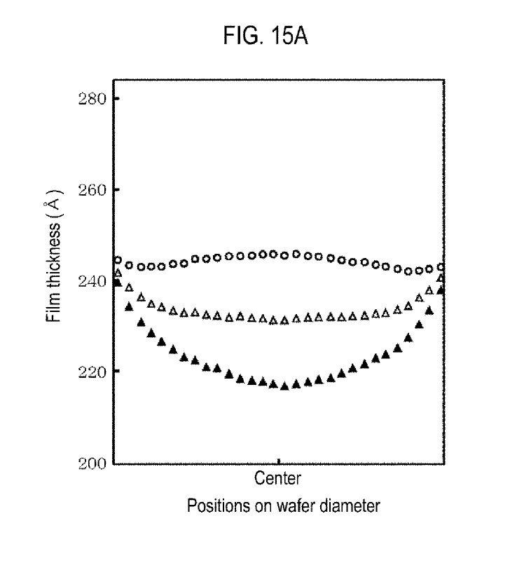

As a result of calculation of the in-plane film thickness uniformity with respect to the wafers positioned in the central height region, the results shown in FIG. 14 were obtained. In FIG. 14, the horizontal axis indicates the wafers mounted on the wafer boat and the vertical axis indicates the in-plane film thickness uniformity. The film thickness uniformity in the case of using the first and second nozzles 81 and 82 is plotted with ⋄. The film thickness uniformity in the case of using only the first nozzle 81 is plotted with Δ. The film thickness uniformity in the case of using only the second nozzle 82 is plotted with □. As shown in FIG. 14, it was confirmed that the wafers W positioned in the central height region are also superior in the in-plane film thickness uniformity. As mentioned above, the inter-plane film thickness uniformity is improved in the region where the source gas is supplied from both the first nozzle 81 and the second nozzle 82. In view of this, it is expected that high inter-plane film thickness uniformity can be obtained in the configuration in which, just like the first embodiment, the gas ejection holes 431 and 441 for ejecting the gas toward the surfaces of all the wafers mounted on the wafer boat 3 are formed in the first and second nozzles 43 and 44.

As a result of finding a film thickness distribution pattern, it was demonstrated that the in-plane film thickness distribution pattern is changed if the film thickness grows larger in the boundary between the region where the gas ejection holes 811 and 821 of the first and second nozzles 81 and 82 overlap with each other and the other regions. However, it was confirmed that the in-plane film thickness uniformity is superior in both the region where the gas ejection holes 811 and 821 overlap with each other and the other regions. Thus, if the film thickness is small, the in-plane film thickness distribution pattern is not significantly changed between the region where the gas ejection holes 811 and 821 overlap with each other and the other regions. It can be said that the configuration of the second embodiment remains effective.

### Evaluation Test 3-1

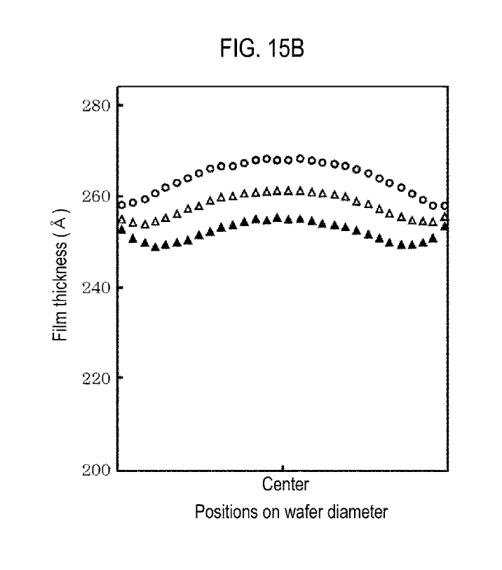

The vertical film forming apparatus provided with the first nozzle 43 was used. 120 monitoring wafers (bare wafers) were mounted at an arrangement interval of 8 mm SiN films were formed by performing a film forming process pursuant to the same sequences as described above except that the source gas is not supplied from the second nozzle 44. Film forming conditions used at this time are as follows. The wafer temperature is 500 degrees C. The supply time of high-frequency power is 20 seconds. The total supply amount of the source gas supplied from the first nozzle 43 is 1.14 liters. The internal pressure of the first tank 61 is 42,000 Pa. Film thicknesses of a plurality of points on the diameter of the wafers were measured with respect to the wafers arranged at predetermined positions on the wafer boat 3. The same tests were performed with respect to the wafers having a pattern surface area of three-folds and the wafers having a pattern surface area of five-folds. The results are shown in FIG. 15A. In FIG. 15A, the horizontal axis indicates the locations on the wafer diameter and the vertical axis indicates the film thickness. In FIG. 15A, the data for the monitoring wafers are plotted with ∘, the data for the wafers having a pattern surface area of three-folds are plotted with Δ, and the data for the wafers having a pattern surface area of five-folds are plotted with ▴.

As a result, it was confirmed that the film thickness and the in-plane film thickness distribution pattern vary depending on the pattern surface area. In the monitoring wafers, the film thickness is substantially uniform within the wafer plane. In the wafers having a pattern surface area of three-folds and the wafers having a pattern surface area of five-folds, the film thickness in the central region of the wafers is smaller than the film thickness in the peripheral edge region thereof, whereby a valley-shaped film thickness distribution appears. It was also found that, if the pattern surface area is increased, the film thickness in the central region of the wafers becomes smaller. It is presumed that a large amount of gas is consumed in the peripheral edge region of the wafers, which means that a sufficient amount of source gas does not reach the center of the wafers.

### Evaluation Test 3-2

A test was conducted in the same manner as in evaluation test 3-1 except that 60 wafers W are mounted on the wafer boat at an arrangement interval of 16 mm. The results are shown in FIG. 15B. In FIG. 15B, the data for the monitoring wafers are plotted with ∘, the data for the wafers having a pattern surface area of three-folds are plotted with Δ, and the data for the wafers having a pattern surface area of five-folds are plotted with ▴. As a result, it was confirmed that the film thickness varies depending on the pattern surface area but the in-plane film thickness distribution pattern is substantially uniform. There appears a mountain-shaped film thickness distribution in which the film thickness in the central region of the wafers is larger than the film thickness in the peripheral edge region thereof. The reason is presumed to be as follows. By reducing the number of the wafers mounted, the consumption amount of the source gas required in all the wafers is reduced. It is possible to supply a sufficient amount of the source gas to all the wafers under the aforementioned supply conditions. Thus, the source gas is spread over not only the peripheral edge region of the wafers but also the central region thereof. From this test, it is understood that the in-plane film thickness distribution of the wafers can be improved by increasing the supply amount of the source gas supplied to the wafers.

According to the present disclosure, when the film forming process is performed by alternately supplying the source gas and the reaction gas into the vertical reaction vessel kept at a vacuum atmosphere, the source gas accumulated in the first tank and the second tank in a pressurized state is supplied through the first source gas nozzle and the second source gas nozzle. The gas ejection holes of both of the first source gas nozzle and the second source gas nozzle are disposed at a central height region in an arrangement direction of the height region in which the substrates are arranged. The gas ejection holes of at least one of the first source gas nozzle and the second source gas nozzle are disposed in the regions other than the central height region. Since the tanks for increasing the pressure are independently installed with respect to the two source gas nozzles, it is possible to supply the source gas into the reaction vessel at a large flow rate. The source gas is ejected from both of the first source gas nozzle and the second source gas nozzle toward the central height region in the substrate-arrangement-direction where the source gas is difficult to reach. Thus, the source gas is spread over each of the plurality of substrates held in a shelf form by the substrate holder. It is therefore possible to obtain high inter-plane film thickness uniformity.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus configured to form films on a plurality of substrates by alternately supplying a source gas and a reaction gas, which reacts with the source gas to form a reaction product, into the reaction vessel in a state in which a substrate holder holding the plurality of substrates in a shelf form is disposed within a vertical reaction vessel kept at a vacuum atmosphere, the film forming apparatus comprising:
a first source gas nozzle and a second source gas nozzle installed so as to extend in an arrangement direction of the substrates, each of the first source gas nozzle and the second source gas nozzle including a plurality of gas ejection holes formed so as to eject the source gas toward central regions of the substrates at height positions corresponding to gaps between the substrates;
a reaction gas supply unit configured to supply the reaction gas into the reaction vessel;
a first source gas supply line and a second source gas supply line respectively connected to the first source gas nozzle and the second source gas nozzle;
a first tank and a second tank respectively installed on the first source gas supply line and the second source gas supply line, and configured to accumulate the source gas in a pressurized state;
valves respectively installed at upstream and downstream sides of the first tank and at upstream and downstream sides of the second tank; and
an exhaust port configured to evacuate the interior of the reaction vessel,
wherein the gas ejection holes of both of the first source gas nozzle and the second source gas nozzle are disposed at a central height region in an arrangement direction of a height region where the substrates are arranged, and the gas ejection holes of at least one of the first source gas nozzle and the second source gas nozzle are disposed in regions other than the central height region.

2. The apparatus of claim 1, wherein the exhaust port is installed in a sidewall of the reaction vessel along the arrangement direction of the substrates so as to face an arrangement region of the substrates, and
wherein, when the reaction vessel is seen in a plane view, an opening angle between the first source gas nozzle and a left-right-direction center of the exhaust port about a center of the substrates and an opening angle between the second source gas nozzle and the left-right-direction center of the exhaust port about the center of the substrates are 90 degrees or more and less than 180 degrees.

3. The apparatus of claim 2, wherein the first source gas nozzle and the second source gas nozzle are disposed symmetrically in a left-right direction with respect to a straight line which interconnects the center of the substrates and the left-right-direction center of the exhaust port.

4. The apparatus of claim 1, wherein the first tank and the second tank are configured to accumulate the source gas which is continuously introduced from upstream sides of the first tank and the second tank and is pressurized while closing the valves existing at downstream sides of the first tank and the second tank.

5. The apparatus of claim 1, wherein the source gas is ejected from the first source gas nozzle and the second source gas nozzle into the reaction vessel at a flow velocity of 250 cc/min or more and 350 cc/min or less.

6. The apparatus of claim 1, wherein the gas ejection holes of the first source gas nozzle and the gas ejection holes of the second source gas nozzle are disposed in an entire height region where the substrates are arranged.
